(19) United States
(12) Patent Application Publication
(10) Pub. No.: US 2015/0285868 A1
(43) Pub. Date: Oct. 8, 2015

(54) POWERLINE COMMUNICATION FOR MONITORING OF A HIGH NUMBER OF BATTERY CELLS

(71) Applicant: GM GLOBAL TECHNOLOGY OPERATIONS LLC, Detroit, MI (US)

(72) Inventors: MANFRED HERRMANN, Ginsheim-Gustavsburg (DE); JOCHEN LENZ, Hattersheim (DE); SEBASTIAN WINKLER, Wiesbaden (DE)

(21) Appl. No.: 14/671,438

(22) Filed: Mar. 27, 2015

Related U.S. Application Data
(60) Provisional application No. 61/974,820, filed on Apr. 3, 2014.

(51) Int. Cl. G01R 31/36; H01M 16/00; H01M 10/42

(52) U.S. Cl. CPC G01R 31/3648; H01M 10/4257; H01M 10/4207; H01M 16/00; G01R 31/3658; G01R 31/3606; H01M 2010/4271; H01M 2010/4278; H01M 2220/20

(57) ABSTRACT

A battery system including a powerline and a plurality of electrically connected smart battery cells each having a cell monitoring unit. The battery system also includes a host controller in communication with the powerline through a plurality of connection lines, where a plurality of the battery cells between adjacent connection lines is referred to as a cell string. The number of cell strings and the number of battery cells in the system determines transfer function gains for signal levels transmitted from the cell monitoring units to the host controller and signal levels transmitted by the host controller to each of the cell monitoring units.

### CROSS-REFERENCE TO RELATED APPLICATIONS

This application claims the benefit of the priority date of U.S. Provisional Patent Application Ser. No. 61/974,820, titled POWERLINE COMMUNICATION FOR MONITORING OF A HIGH NUMBER OF BATTERY CELLS, filed Apr. 3, 2014.

### BACKGROUND OF THE INVENTION

1. Field of the Invention

This invention relates generally to a battery system that monitors a high number of serial connected battery cells through powerline communications and, more particularly, to a battery system that monitors a high number of smart battery cells each having a communications node, such as more than twenty battery cells as would typically be present in a vehicle propulsion battery, through powerline communications, where the communications nodes are organized in multiple strings by high-frequency, and where the power cabling is a simple series topology.

2. Discussion of the Related Art

Electric vehicles are becoming more prevalent. These vehicles include hybrid vehicles, such as the extended range electric vehicles (EREV), that combine a battery and a main power source, such as an internal combustion engine, fuel cell system, etc., and electric only vehicles, such as the battery electric vehicles (BEV). These batteries can be different battery types, such as lithium-ion, nickel metal-hydride, lead-acid, etc. A typical high voltage battery system for an electric vehicle may include several battery cells electrically coupled in series to provide the vehicle power and energy requirements. The battery cells may be grouped into battery modules, where the cells in a module are electrically coupled in series and/or parallel. The number of cells in a module and the number of modules in a vehicle depends on the battery technology and application. For example, for lithium-ion type battery modules it is common to have eight to sixteen cells electrically connected in series in a module. Different vehicles may have different battery designs that employ various trade-offs and advantages for a particular application.

As a result of many factors, such as cell self-discharge rate, internal cell resistance, electrical connections, battery aging, etc., the state-of-charge (SOC) of the cells in the battery may drift apart during operation of the battery over time. A battery management system (BMS) may be provided to monitor the cell voltage, impedance, state-of-health, state-of-charge (SOC), temperature, etc. of each battery cell, and control how much the battery can be charged and discharged based on the SOC of the maximum charged cell and the minimum charged cell.

In one known vehicle battery design, each battery module includes a cell sensing board (CSB), where each cell in the module is electrically coupled to the CSB. The CSB receives analog voltage signals from each battery cell in the module and uses filtering circuits, multiplexers, analog-to-digital (A/D) converters, etc. to send the voltage signals on a digital wired communications link to the BMS.

One BMS architecture has been investigated that eliminates the need for the CSB in each battery module. Particularly, it has been proposed in the art to provide what are sometimes referred to as “smart cells” that include a low cost electronic monitoring unit integrated into each cell that includes electronics for monitoring the voltage and temperature of the cell, and to control the state-of-charge, etc. of individual cells. More particularly, each battery cell is equipped with an integrated electronic circuit that is part of the cell structure itself. Each electronic monitoring unit in each smart cell is part of the communications link from each smart-cell to a BMS-host so that the protocol works as a star (host to slaves) topology.

A typical vehicle of the type discussed above will often include a relatively large number of individual battery smart cells electrically coupled in series, where the separate monitoring unit in each cell provides communications signals to a single host controller and the host controller provides command signals to each of the individual battery cells. Because the number of battery cells being monitored by the host controller is relatively large, traditional communications techniques, such as a CAN bus, typically are not effective for such communications. One technique to overcome this limitation is to employ powerline communications, well known to those skilled in the art, where the high voltage line coupled to the cells in the battery module is also used for communications purposes. The controller and the several cell monitoring units will modulate digital bits onto a carrier wave propagating on the powerline for data transfer to provide the communications signal.

### SUMMARY OF THE INVENTION

This present disclosure describes a battery system including a powerline and a plurality of electrically connected smart battery cells each having a cell monitoring unit. The battery system also includes a host controller in communication with the powerline through a plurality of connection lines, where a plurality of the battery cells between adjacent connection lines is referred to as a cell string. The number of cell strings and the total number of battery cells in the system determines transfer function gains for signal levels transmitted from the cell monitoring units to the host controller and signal levels transmitted by the host controller to each of the cell monitoring units.

Additional features of the present invention will become apparent from the following description and appended claims, taken in conjunction with the accompanying drawings.

### BRIEF DESCRIPTION OF THE DRAWINGS

FIG. 1 is a schematic diagram of a known battery system employing full battery system coupling to a powerline;

FIG. 2 is a schematic diagram of a battery system employing half-pack battery coupling to a powerline;

FIG. 3 is a schematic diagram of a battery system employing multi-pack battery coupling to a powerline;

FIG. 4 is a schematic diagram of a battery system including a plurality of battery cells each having a smart cell monitoring unit and including multi-pack battery coupling to a powerline;

FIG. 5 is a high frequency equivalent circuit diagram for the battery system shown in FIG. 4;

FIG. 6 is a simplified equivalent circuit diagram of the circuit shown in FIG. 5;

FIG. 7 is an equivalent circuit for slave-to-host signaling; and

FIG. 8 is a graph with number of cell strings on the horizontal axis and signal gain on the vertical axis showing host-to-slave and slave-to-host signal gain.

### DETAILED DESCRIPTION OF THE EMBODIMENTS

The following discussion of the embodiments of the invention directed to a battery system employing powerline communications for a high number of battery cells is merely exemplary in nature, and is in no way intended to limit the invention or its applications or uses. For example, the battery system described herein is for a vehicle application, however, the battery system will also have application for stationary systems.

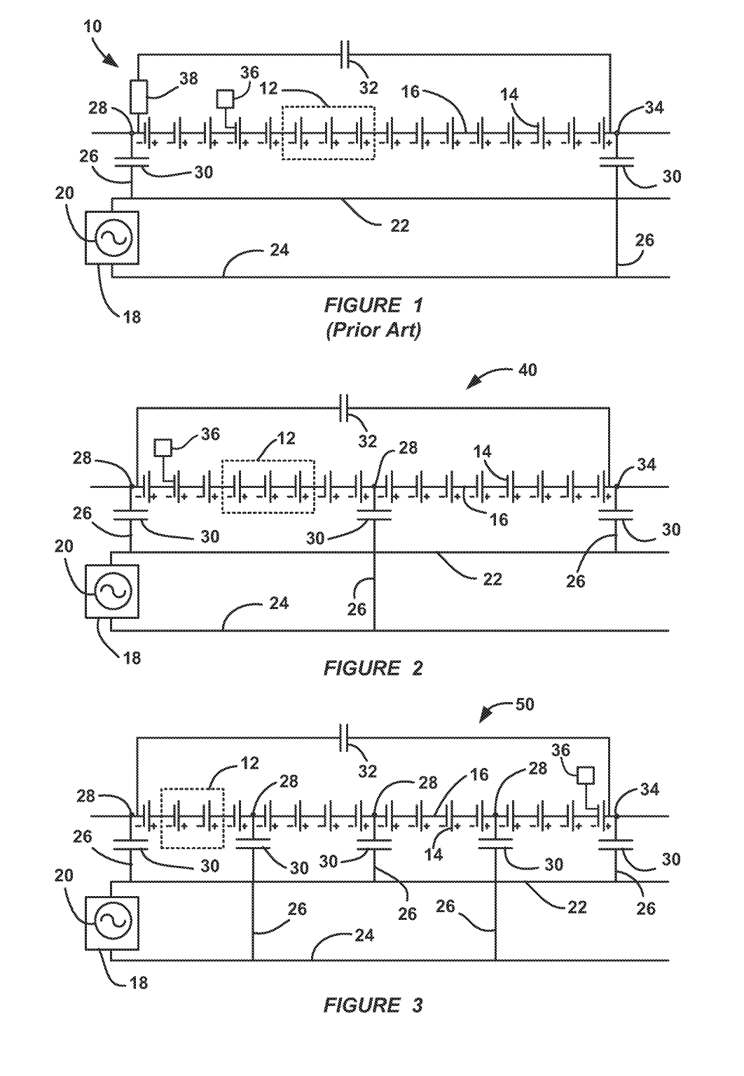

FIG. 1 is a schematic diagram of a known battery system 10 including multiple battery modules 12 and having a number of smart battery cells 14 electrically coupled in series along a powerline 16. The electrical configuration of the smart cells 14 is intended to represent any suitable configuration of battery cells including groups of series connected or parallel connected cells. The cells 14 are smart cells in that each cell or small groups of cells include a separate monitoring unit 36 providing cell monitoring and communications purposes, as discussed above. It is noted that the number of the cells 14 in the battery system 10 shown here is sixteen, which is merely for illustration purposes only, where a typical battery pack for a vehicle may include a 100 or more battery cells. Further, it is noted that the battery cells 14 are intended to represent any suitable battery cell for a vehicle that is capable of employing smart cell technology, such as lithium-ion, nickel metal-hydride, lead-acid, etc.

The battery system 10 includes a host interface controller 18 having a signal generator 20 that provides communication signals on and receives communication signals from communications lines 22 and 24, where the communications lines 22 and 24 are electrically coupled to the powerline 16. Particularly, connections lines 26 each including a capacitor 30 are coupled to the communications lines 22 or 24 and nodes 28 in the powerline 16, where end node 34 represents a positive battery terminal. In this manner, the controller 18 is able to provide communications signals on the powerline 16 and receive communications signals from the powerline 16. The smart cell monitoring unit 36 in each of the cells 14 provides communications signals on the powerline 16 to be received by the host controller 18 that specifically identifies operation of that cell, such as cell voltage, cell temperature, etc., and the controller 18 provides signals on the powerline 16 to the smart cells 14 that controls the cells 14, such as for resistive cell balancing, SOC charge limitation, etc.

Because there are a relatively large number of the battery cells 14 between the nodes 28 and 34 shown in the system 10, the known smart cell powerline communications technique often suffers from low signal-level affects. Further, because there are only two connection points at the nodes 28 and 34 to the powerline 16 for the battery pack 12, communications signal levels on the powerline 16 to the cells 14 are divided by the number of the cells 14 so that only a very low signal level can be received from the monitoring unit on the cell 14. As will be discussed in detail below, the present invention proposes providing multiple, i.e., more than two, connection points from the host interface controller 18 to the powerline 16 so as to have multiple inputs to the communications lines 22 and 24 to overcome these limitations.

In the state-of-the-art powerline topology, the system 10 would include an X-capacitor 32 electrically coupled to the powerline 16 and across the battery cells 14, as shown. Such a capacitor typically exists in any connected high voltage (HV) device, such as drive systems, chargers, auxiliary power modules, etc., to induce significant damping to the signals between the lines 22 and 24, and would require a decoupling element 38.

FIG. 2 is a schematic diagram of a battery system 40 similar to the battery system 10 and showing half-pack battery coupling, where like elements are identified by the same reference number. In the battery system 40, additional connection lines 26 including capacitors 30 are provided between the communications line 22 or 24 and the powerline 16, where all of the connection lines 26 and the capacitors 30 are alternately coupled to the lines 22 and 24. In this design, the number of the smart cells 14 between two particular nodes 28 or one of the nodes 28 and the node 34 on the powerline 16 is reduced in half. Therefore, communications between the smart cells 14 and the host controller 18 provides a better balance because there are two signal “injections” from the nodes 28 and 34 to the communications lines 22 and 24.

It is noted that as used herein, a segment of battery cells along the powerline 16 between two nodes 28 is referred to as a cell string, where the system 40 includes two cell strings. It is further noted that providing three connection lines between the powerline 16 and the communications lines 22 and 24 as shown in the system 40 is intended for illustration purposes only. Other designs will likely employ a greater number of cell strings depending on the number of the cells 14 and the desired signal levels and communications paths. The discussion below provides a technique for determining an optimal number of the cell strings for a particular battery system. Also, although it is generally practical for a real implementation, and assumed for the calculation method discussed below, to have the same number of the battery cells 14 in all of the cell strings, it is not a requirement that such be the case.

FIG. 3 is a schematic diagram of a battery system 50 of another embodiment showing multi-pack battery coupling including four cell strings, where like elements to the system 40 are identified by the same reference numbers. In the system 50, two more connection points are provided between the powerline 16 and the communications lines 22 and 24, as shown.

In the systems 40 and 50, the X-capacitors 32 are coupled to the communications line 22 only to prevent damping of the signal between the lines 22 and 24, and thus the decoupling element 38 is not required. In general, this is true for any topology with an even number of cell strings. Thus, this robustness against external X-capacitors is a benefit of the proposed battery cell system topology.

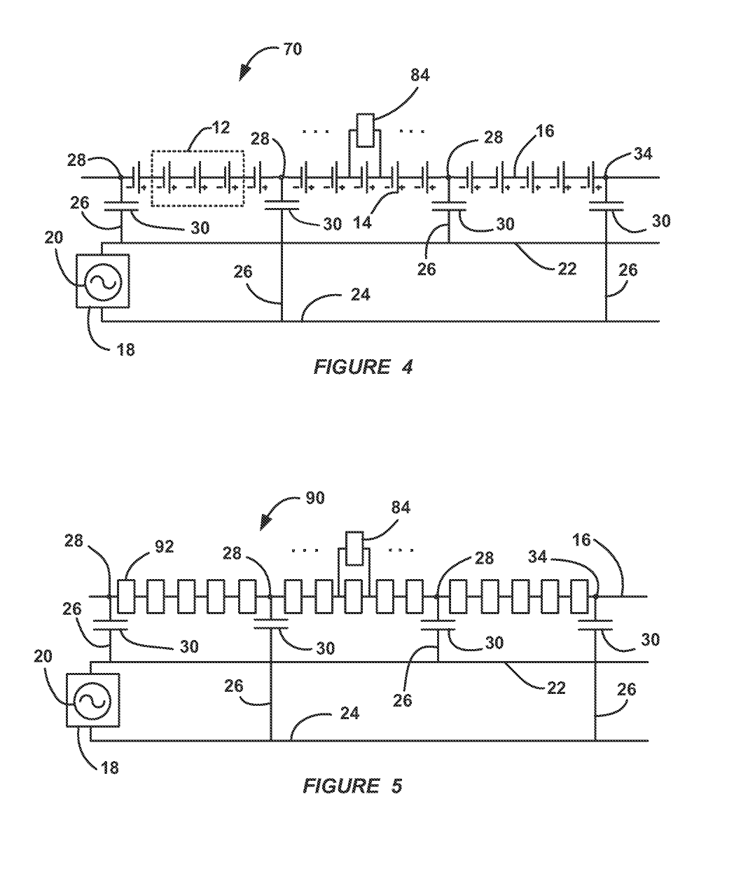

FIG. 4 is a schematic diagram of a battery system 70 similar to the battery systems discussed above, where like elements are identified by the same reference numbers, and where the system 70 provides a better illustration of a physical battery system. In this implementation, the host controller 18 is electrically coupled to the powerline 16 through multiple connection lines 26 and capacitors 30. Further, a slave controller 84 is shown coupled to one of the cells 14 and is intended to represent the smart cell monitoring unit 36 within that cell 14 that provides cell voltage and temperature monitoring, and cell resistive balancing. Each of the cells 14 in the system 70 will include a slave controller 84.

FIG. 5 is an equivalent circuit diagram 90 of the battery system 70, where like elements are identified by the same reference number. The powerline communications employed by a typical vehicle battery system will be a high frequency communications line, typically in the range of 1-100 MHz. Because of the high frequency communications, each of the battery smart cells 14 will look like impedance Z_{b}, represented as impedance elements 92, to the signals propagating on the powerline 16. Further, each of the capacitors 30 in the connection lines 26, respectively, will have coupling impedance Z_{c}. However, the electrical architecture and values of the capacitors 30 assumes that the coupling impedance Z_{c} is much less than the cell impedance Z_{b}, which means that the capacitors 30 can be replaced with short circuits in the equivalent circuit diagram.

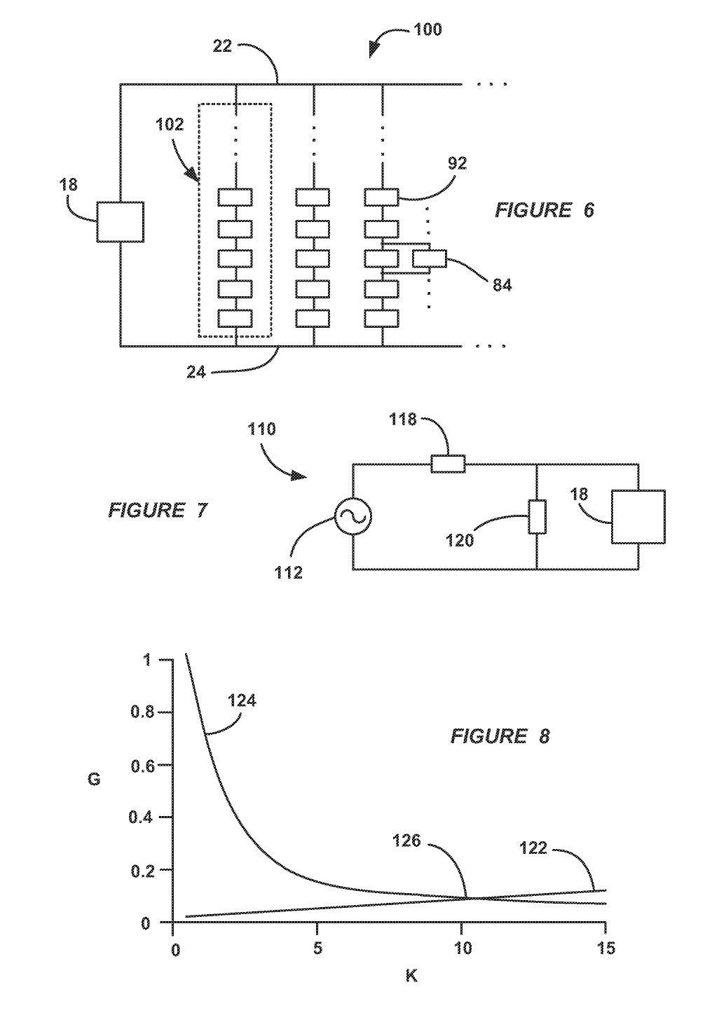

With this in mind, FIG. 6 is an equivalent circuit diagram 100 of the system 70, where each of the cell strings between the particular nodes is represented as a cell string 102 between the communications lines 22 and 24. The number of the impedance elements 92 in each of the strings 102, also referred to herein as K, and the number of the strings 102 in the battery system 70 is left open in this diagram as will become apparent from the discussion below. Further, for the discussion below, it is assumed that all of the cell impedances Z_{b} for all of the cells 14 is the same. Also, it is noted that the number of the cells 14 in each of the strings 102 is the same, however, this is not a requirement of the invention, but may be desirable in a practical implementation.

As discussed above, there are two communications directions for the particularly battery monitoring system, namely, signals sent from the host interface controller 18 to the slave controllers 84, and signals sent from the slave controllers 84 to the host interface controller 18. For each of these transmission directions, it is necessary to determine the transfer function gain G of the voltage U₂ received at the host interface controller 18 or the slave controller 84 relative to the transmitted voltage U₁ from the slave controller 84 to the host controller 18. It is noted that for this discussion, the voltage of the transmitted signal is U₁ whether it is transmitted from the host controller 18 or the slave controller 84, and the voltage of the received signal is U₂ whether it is received at the host controller 18 or the slave controller 84.

First take the case where the host interface controller 18 is transmitting a signal with voltage U₁ that is received by a particular slave controller 84 having voltage U₂. In this communications direction, the host interface controller 18 is at very low impedance and the receiving slave controller 84 is at very high impedance. Based on the assumptions herein, equations (1)-(3) can be used to determine the transfer function gain Gₕₛ as the relationship between these voltages. Based on this analysis, it can be shown that the transfer function gain Gₕₛ is the inverse of the number of the cells per string, which can be used to determine how many cell strings K are desired for a particular design, where N is the number of cells 14 per string K, and KN is the total number of the cells 14.

$$\begin{matrix}{U}_{x} = \vert \underline{{U}_{x}} \vert & ( 1 ) \\ {U}_{2} = \frac{{U}_{1}}{N} & ( 2 ) \\ {G}_{hs} = \frac{1}{N} = \frac{K}{NK} & ( 3 )\end{matrix}$$

As mentioned above, for communications signals from one of the slave controllers 84 to the host controller 18, it is assumed that the slave controller 84 is at very low impedance and the host controller 18 is at very high impedance. Further, it is assumed that the number of the cells 14 in a particular string is significantly greater than 1. FIG. 7 is an equivalent circuit 110 for the transmission of signals from the slave controller 84 to the host interface controller 18, where a signal generator 112 generates the transmitted voltage U₁ at the slave controller 84 and the received voltage U₂ is at the controller 18. Circuit element 118 represents the combined impedance of all of the other cells 14 in the same string 102 that the transmitting slave controller 84 is in and impedance element 120 represents the combined impedance of all of the other cells in all of the other strings, where the impedance element 118 has impedance (N−1)Z_{b} and the impedance element 120 has impedance

$$( \frac{N}{K - 1} ) {Z}_{b} .$$

All of the impedance elements 92 in a particular string 102 can be reduced to a single impedance element defined by NZ_{b}. Based on these assumptions and the equivalent circuit 110, the transfer function gain Gₛₕ from the slave controller 84 to the host controller 18 is defined by equations (4)-(6) below as 1/K.

$$\begin{matrix}{G}_{sh} = \frac{{U}_{2}}{{U}_{1}} = \frac{( \frac{N}{K - 1} ) {Z}_{b}}{( N - 1 ) {Z}_{b} + ( \frac{N}{K - 1} ) {Z}_{b}} & ( 4 ) \\ {G}_{sh} = \frac{N}{1 + K ( N - 1 )} & ( 5 ) \\ {G}_{sh} \approx \frac{1}{K} & ( 6 )\end{matrix}$$

FIG. 8 is a graph with string count K on the horizontal axis and transfer function gain G on the vertical axis showing the relationship between the transmission gain of a signal from the host controller 18 to one of the slave controllers 84 on line 122 and the transmission gain of a signal from one of the slave controllers 84 to the host controller 18 on line 124. As can be seen, the signal gain for transmissions from one of the slave controllers 84 to the host controller 18 on the line 124 is very good for just a few strings, but is relatively poor for transmission signal gain from the host controller 18 to one of the slave controllers 84. As the number of the strings increases, the gain of the transmission signals from one of the slave controllers 84 to the host controller 18 decreases, but the gain of the transmission signals from the host controller 18 to one of the slave controllers 84 increases. In this specific non-limiting example for about 100 battery cells, the lines 122 and 124 cross at point 126, which is about ten strings. Considering the optimal string count to be when the two transfer function gains are the same, the number of the strings for a particular cell count can be determined as the square root of the total cell count based on equations (7)-(10).

$$\begin{matrix}{G}_{hs} = {G}_{sh} & ( 7 ) \\ \frac{K}{NK} = \frac{1}{K} & ( 8 ) \\ {K}^{2} = NK & ( 9 ) \\ K = \sqrt{NK} = \sqrt{TotalCellCount} & ( 10 )\end{matrix}$$

As will be well understood by those skilled in the art, the several and various steps and processes that may have been discussed herein to describe the invention may be referring to operations performed by a computer, a processor or other electronic calculating device that manipulate and/or transform data using electrical phenomenon. Those computers and electronic devices may employ various volatile and/or non-volatile memories including non-transitory computer-readable medium with an executable program stored thereon including various code or executable instructions able to be performed by the computer or processor, where the memory and/or computer-readable medium may include all forms and types of memory and other computer-readable media.

The foregoing discussion disclosed and describes merely exemplary embodiments of the present invention. One skilled in the art will readily recognize from such discussion and from the accompanying drawings and claims that various changes, modifications and variations can be made therein without departing from the spirit and scope of the invention as defined in the following claims.

What is claimed is:

1. A battery system comprising:
a powerline;
a plurality of battery cells electrically coupled along the powerline, each battery cell including a battery cell monitoring unit that monitors parameters of the battery cell and provides a communications interface to the powerline;
a plurality of communications lines where each communications line is electrically coupled to the powerline by a plurality of connection lines, wherein a first connection line is electrically coupled to a first end of the powerline and a second connection line is electrically coupled to a second end of the powerline so that all of the battery cells are between the first and second connection lines, and wherein at least one other connection line is electrically coupled to the powerline between the first and second connection lines so that a plurality of battery cells are electrically coupled along the powerline between the first connection line and the other connection line and a plurality of battery cells are electrically coupled along the powerline between the second connection line and the other connection line, and wherein the battery cells between two adjacent connection lines is defined as a cell string; and
a controller that controls signals provided on the communications lines.

2. The battery system according to claim 1 wherein the number of connection lines is at least four connection lines providing at least three cell strings.

3. The battery system according to claim 2 wherein the connections lines alternate between being connected to the one of the communications lines and the other communications line.

4. The battery system according to claim 1 wherein the plurality of communications lines is two communications lines.

5. The battery system according to claim 1 wherein the number of the cell strings is determined by the number of the battery cells in the battery system.

6. The battery system according to claim 5 wherein the number of the cell is determined by a transfer function gain of transmission signals transmitted from the controller to one of the battery cells and a transmission function gain of transmission signals transmitted from one of the battery cells to the controller.

7. The battery system according to claim 6 wherein the number of the cell strings is determined when the transfer function gains are about the same.

8. The battery system according to claim 6 wherein the transfer function gain of the transmission signals from the cell to the controller and the transfer function gain of the transmission signals from the battery controller to the cell is based on impedance of the battery cell.

9. The battery system according to claim 5 wherein the number of the cell strings is determined by a square root of the total number of battery cells in the battery system.

10. The battery system according to claim 1 further comprising an X-capacitor coupled to the powerline that does not require a decoupling element.

11. The battery system according to claim 1 wherein the battery cells are smart cells.

12. The battery system according to claim 1 wherein the parameters include voltage and temperature of the battery cell.

13. The battery system according to claim 1 wherein the battery system is a vehicle battery system.

14. A vehicle battery system comprising:
a powerline;
a plurality of battery smart cells electrically coupled along the powerline, each battery cell including a battery cell monitoring unit that monitors parameters of the battery cell and provides a communications interface to the powerline; and
first and second communications lines, a first connection line electrically coupled to a first end of the powerline and the first communications line, a second connection line electrically coupled to a second end of the powerline and the first communications line, a third connection line electrically coupled to the second communications line and the powerline between the first and second ends of the powerline, a fourth connection line electrically coupled to the first communications line and the powerline between the first and second ends of the powerline and a fifth connection line electrically coupled to the second communications line and the powerline between the first and second ends of the powerline so that a plurality of the battery cells are electrically coupled along the powerline between the first and third connection lines, the third and fourth connection lines, the fourth and fifth connection lines, and the fifth and second connection lines.

15. The battery system according to claim 14 further comprising an X-capacitor coupled to the powerline that does not require a decoupling element.

16. A vehicle battery system comprising:
a powerline;
a plurality of battery cells electrically coupled along the powerline, each battery cell including a battery cell monitoring unit that monitors parameters of the battery cell and provides a communications interface to the powerline;
first and second communications lines electrically coupled to the powerline by a plurality of connection lines, wherein a first connection line is electrically coupled to a first end of the powerline and a second connection line is electrically coupled to a second end of the powerline so that all of the battery cells are between the first and second connection lines, and wherein a plurality of other connection lines are electrically coupled to the powerline and the first and second communications lines in an alternating manner between the first and second connection lines so that a plurality of battery cells are electrically coupled along the powerline between adjacent connection lines, and wherein the battery cells between two adjacent connection lines is defined as a cell string; and
a controller that controls signals provided on the communications lines.

17. The battery system according to claim 16 wherein the number of the cell strings is determined by the number of the battery cells in the battery system.

18. The battery system according to claim 17 wherein the number of the cell is determined by a transfer function gain of transmission signals transmitted from the controller to one of the battery cells and a transmission function gain of transmission signals transmitted from one of the battery cells to the controller.

19. The battery system according to claim 18 wherein the number of the cell strings is determined when the transfer function gains are about the same.

20. The battery system according to claim 17 wherein the number of the cell strings is determined by a square root of the total number of battery cells in the battery system.
